(19) United States
(12) Patent Application Publication
(10) Pub. No.: US 2014/0205769 A1
(43) Pub. Date: Jul. 24, 2014

(54) CASCADED PLASMA REACTOR

(71) Applicant: Veeco ALD Inc., Fremont, CA (US)

(72) Inventor: Sang In Lee, Sunnyvale, CA (US)

(73) Assignee: Veeco ALD Inc., Fremont, CA (US)

(21) Appl. No.: 14/155,200

(22) Filed: Jan. 14, 2014

Related U.S. Application Data
(60) Provisional application No. 61/755,353, filed on Jan. 22, 2013.

(51) Int. Cl. C23C 16/50

(52) U.S. Cl. CPC C23C 16/50
USPC 427/569; 118/723 R; 118/719; 118/720

(57) ABSTRACT

Embodiments relate to a plasma reactor including two or more sub-plasma reactors connected in series to generate an increased amount or increase the reactivity of radicals and reactive species. The two sub-plasma reactors may be of the same type or a different type. The plasma reactor including two or more sub-plasma reactors connected in series is advantageous, among other reasons, because smaller space is used compared to having multiple plasma reactors placed on tandem.

### CROSS-REFERENCE TO RELATED APPLICATION

This application claims priority under 35 U.S.C. §119(e) to co-pending U.S. Provisional Patent Application No. 61/755,353, filed on Jan. 22, 2013, which is incorporated by reference herein in its entirety.

### BACKGROUND

The present disclosure relates to a plasma reactor for generating radicals of gas for injection onto a substrate.

Plasma is partially ionized gas consisting of large concentrations of excited atomic, molecular, ionic, and free-radical species. The reactive species or radicals generated by plasma can be used for various purposes, including (i) chemically or physically modifying the characteristics of a surface of substrate by exposing the surface to the reactive species or radicals, (ii) performing chemical vapor deposition (CVD) by causing reaction of the reactive species or radicals and source precursor in a vacuum chamber, and (iii) performing atomic layer deposition (ALD) by exposing a substrate adsorbed with source precursor molecules to the reactive species or radicals.

There are two different types of plasma reactors: (i) a direct plasma reactor, and (ii) a remote plasma reactor. The direct plasma reactor generates plasma that comes into contact directly with the substrate. The direct plasma reactor may generate energetic particles (e.g., free radicals, electrons and ions) and radiation that directly come into contact with the substrate. Such contact may cause damage to the surface of the substrate and also disassociate source precursor molecules adsorbed in the substrate. Hence, the direct plasma reactor has limited use in fabrication of semiconductor devices or organic light emitting diode (OLED) devices.

A remote plasma device generates plasma at a location remote from the substrate. Hence, the remote plasma device is less likely to cause damage to the substrate. However, in a remote plasma device, the radicals or reactive species generated by the plasma needs to travel across a certain distance to the substrate. While traveling, the radicals or the reactive species may revert back to low reactive state or dissipate. Therefore, the amount of radicals or reactive species generated in the remote plasma device tends to be smaller than a comparable direct plasma reactor.

### SUMMARY

Embodiments relate to a remote plasma reactor with a plurality of sub-plasma reactors cascaded to increase the amount or reactivity of radicals or reactive species generated in the remote plasma reactor. Each sub-plasma reactor includes a chamber for generating plasma. By applying energy to gas within a first sub-plasma reactor, plasma is formed in the plasma chamber to generate a first excited gas. The first excited gas is then injected into a second sub-plasma reactor to generate a second excited gas that is more reactive or excited than the first excited gas.

In one embodiment, the first sub-plasma reactor includes a first inner electrode and a first outer electrode defining a first chamber of the first sub-plasma reactor. A voltage difference is applied between the first inner electrode and the first outer electrode to generate plasma in the first chamber to excite gas within the first chamber. The second sub-plasma reactor includes a second inner electrode and a second outer electrode defining a second chamber of the second sub-plasma reactor. A voltage difference is applied between the second inner electrode and the second outer electrode to excite gas within the second chamber.

In one embodiment, the first sub-plasma reactor and the second sub-plasma reactor include a body formed with at least one channel for circulating cooling medium to cool the plasma reactor.

In one embodiment, the second sub-plasma reactor is formed with an exposure chamber open towards the substrate and having a width larger than a gap between the second sub-plasma reactor and the substrate.

In one embodiment, the first and second sub-plasma reactors are capacitively coupled plasma (CCP) type sub-plasma reactors.

In one embodiment, the first sub-plasma reactor and the second sub-plasma reactor are of different types.

In one embodiment, the first sub-plasma reactor is an inductively coupled plasma (ICP) type sub-plasma reactor and the second sub-plasma reactor is a capacitively coupled plasma (CCP) type sub-plasma reactor.

In one embodiment, the first sub-plasma reactor includes a coil surrounding the first chamber and electric current passes the coil to induce plasma within the first chamber.

In one embodiment, the plasma reactor includes a third sub-plasma reactor connected to the first sub-plasma reactor to receive the first excited gas. The third sub-plasma reactor is formed with a third chamber and is configured to generate a third excited gas that is more reactive or excited than the first excited gas. The third sub-plasma reactor injects the third excited gas onto the substrate.

In one embodiment, the second sub-plasma reactor and the third sub-plasma reactor are placed in tandem.

In one embodiment, different portions of the substrate are successively injected with the second excited gas as the substrate passes the second sub-plasma reactor.

### BRIEF DESCRIPTION OF DRAWINGS

FIG. 1 is a cross sectional diagram of a linear deposition device, according to one embodiment.

FIG. 2 is a perspective view of a linear deposition device, according to one embodiment.

FIG. 3 is a perspective view of a rotating deposition device, according to one embodiment.

FIG. 4 is a perspective view of a plasma reactor, according to one embodiment.

FIG. 5 is a cross sectional view of the plasma reactor taken along line A-B of FIG. 4, according to one embodiment.

FIG. 6 is a perspective view of a plasma reactor with an exhaust outlet and a gas inlet, according to one embodiment.

FIG. 7 is a perspective view of a plasma reactor with a pair of exhaust outlets, according to one embodiment.

FIG. 8 is a cross sectional view of a plasma reactor with two capacitively coupled plasma (CCP) type sub-plasma reactors, according to one embodiment.

FIG. 9 is a sectional view of a plasma reactor with an inductively coupled plasma (ICP) type sub-plasma reactor and a CCP type sub-plasma reactor, according to one embodiment.

FIG. 10 is a perspective view of the plasma reactor of FIG. 9, according to one embodiment.

FIG. 11 is a perspective view of a plasma reactor including an ICP type sub-plasma reactor and two CCP type sub-plasma reactors, according to one embodiment.

### DETAILED DESCRIPTION OF EMBODIMENTS

Embodiments are described herein with reference to the accompanying drawings. Principles disclosed herein may, however, be embodied in many different forms and should not be construed as being limited to the embodiments set forth herein. In the description, details of well-known features and techniques may be omitted to avoid unnecessarily obscuring the features of the embodiments.

In the drawings, like reference numerals in the drawings denote like elements. The shape, size and regions, and the like, of the drawing may be exaggerated for clarity.

Embodiments relate to a remote plasma reactor including two or more sub-plasma reactors connected in series to generate an increased amount of radicals and reactive species or increase the reactivity of excited gas. The two or more sub-plasma reactors may be of the same type or a different type. The plasma reactor including two or more sub-plasma reactors connected in series is advantageous, among other reasons, because smaller space is used to generate more reactive or more excited gas compared to using multiple plasma reactors placed on tandem.

### Example Apparatus for Performing Deposition

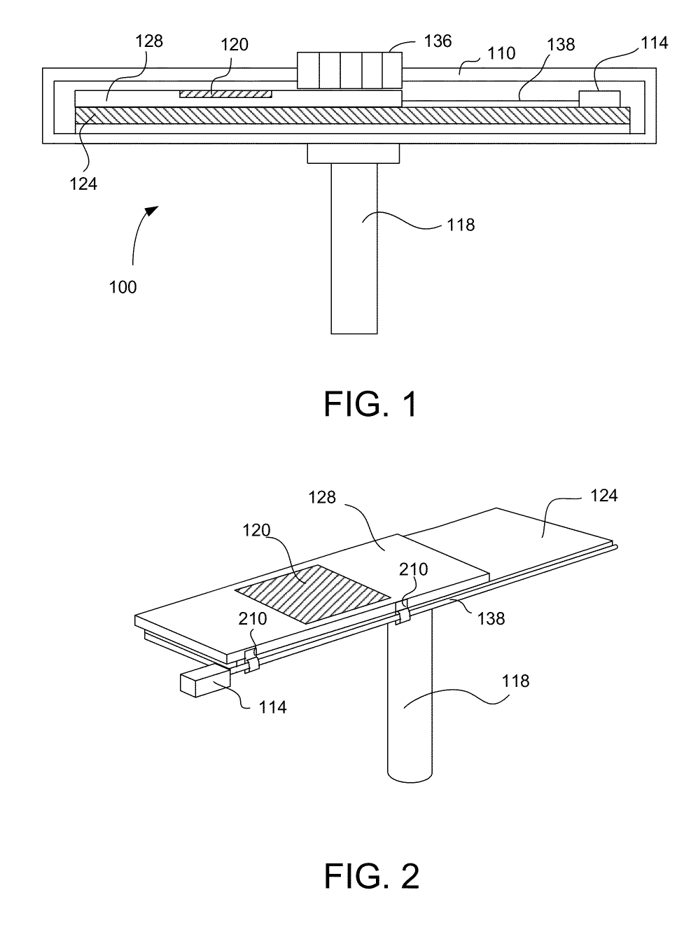

FIG. 1 is a cross sectional diagram of a linear deposition device 100, according to one embodiment. FIG. 2 is a perspective view of the linear deposition device 100 (without chamber walls to facilitate explanation), according to one embodiment. The linear deposition device 100 may include, among other components, a support pillar 118, the process chamber 110 and one or more reactors 136. The reactors 136 may include one or more of injectors and radical reactors for performing molecular layer deposition (MLD), atomic layer deposition (ALD) and/or chemical vapor deposition (CVD). Each of the injectors injects source precursors, reactant precursors, purge gases or a combination of these materials onto the substrate 120.

The process chamber enclosed by walls may be maintained in a vacuum state to prevent contaminants from affecting the deposition process. The process chamber 110 contains a susceptor 128 which receives a substrate 120. The susceptor 128 is placed on a support plate 124 for a sliding movement. The support plate 124 may include a temperature controller (e.g., a heater or a cooler) to control the temperature of the substrate 120.

The linear deposition device 100 may also include lift pins (not shown) that facilitate loading of the substrate 120 onto the susceptor 128 or dismounting of the substrate 120 from the susceptor 128.

In one embodiment, the susceptor 128 is secured to brackets 210 that move across an extended bar 138 with screws formed thereon. The brackets 210 have corresponding screws formed in their holes receiving the extended bar 138. The extended bar 138 is secured to a spindle of a motor 114, and hence, the extended bar 138 rotates as the spindle of the motor 114 rotates. The rotation of the extended bar 138 causes the brackets 210 (and therefore the susceptor 128) to make a linear movement on the support plate 124. By controlling the speed and rotation direction of the motor 114, the speed and the direction of the linear movement of the susceptor 128 can be controlled. The use of a motor 114 and the extended bar 138 is merely an example of a mechanism for moving the susceptor 128. Various other ways of moving the susceptor 128 (e.g., use of gears and pinion or a linear motor at the bottom, top or side of the susceptor 128). Moreover, instead of moving the susceptor 128, the susceptor 128 may remain stationary and the reactors 136 may be moved.

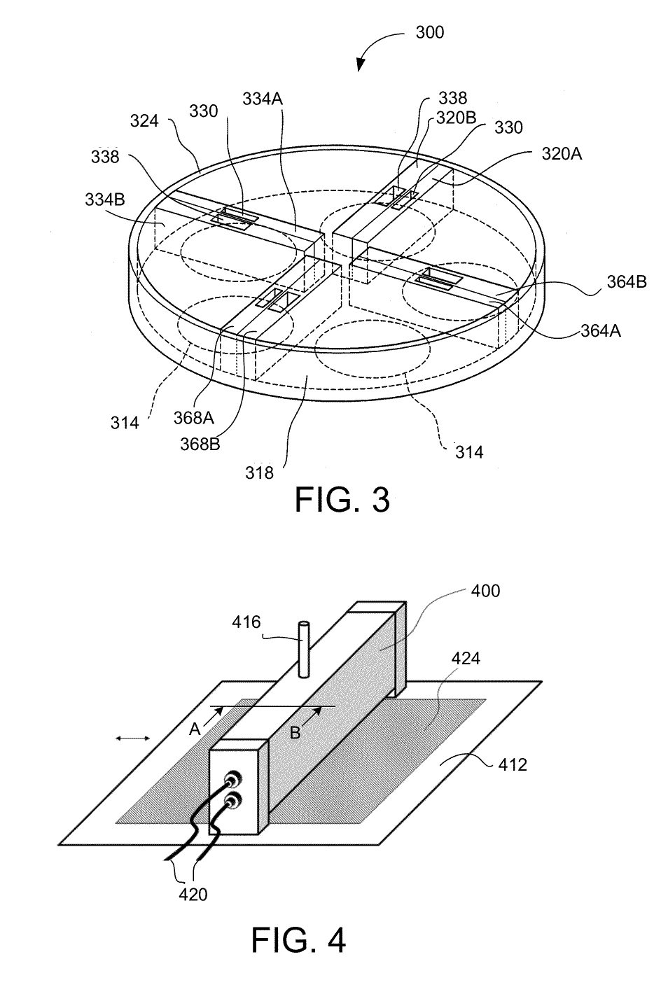

FIG. 3 is a perspective view of a rotating deposition device 300, according to one embodiment. Instead of using the linear deposition device 100 of FIG. 1, the rotating deposition device 300 may be used to perform the deposition process according to another embodiment. The rotating deposition device 300 may include, among other components, reactors 320, 334, 364, 368, a susceptor 318, and a container 324 enclosing these components. A reactor (e.g., 320) of the rotating deposition device 300 corresponds to a reactor 136 of the linear deposition device 100, as described above with reference to FIG. 1. The susceptor 318 secures the substrates 314 in place. The reactors 320, 334, 364, 368 may be placed with a gap from the substrates 314 and the susceptor 318. Either the susceptor 318 or the reactors 320, 334, 364, 368 rotate to subject the substrates 314 to different processes.

One or more of the reactors 320, 334, 364, 368 are connected to gas pipes (not shown) to provide source precursor, reactant precursor, purge gas and/or other materials. The materials provided by the gas pipes may be (i) injected onto the substrate 314 directly by the reactors 320, 334, 364, 368, (ii) after mixing in a chamber inside the reactors 320, 334, 364, 368, or (iii) after conversion into radicals by plasma generated within the reactors 320, 334, 364, 368. After the materials are injected onto the substrate 314, the redundant materials may be exhausted through outlets 330, 338. The interior of the rotating deposition device 300 may also be maintained in a vacuum state.

The reactors 136 of FIG. 1 or reactors 320, 334, 364, 368 may include injectors for injecting source precursor, reactant precursor and/or purge gas as well as plasma reactors for generating and injecting radicals or reactive species, as described below in detail.

Plasma Reactor with Serially Connected Plasma Chambers

FIG. 4 is a perspective view of a plasma reactor 400, according to one embodiment. The plasma reactor 400 is connected to an input port 416 which injects gas into the plasma reactor 400. The plasma reactor 400 is also connected to cables 420 to provide an electric signal to the plasma reactor 400. A substrate 412 moves below the plasma reactor 400 to expose different parts of the substrate 200 to radicals or reactive species generated by the plasma reactor 400, and thereby form a treated surface 424 on the substrate 412. As the substrate 412 is exposed to the radicals or reactive species, the surface of the substrate 412 is transformed by one or more of the processes such as radical-induced oxidation, nitration, carbonization, reduction, hydrolyzation or amination.

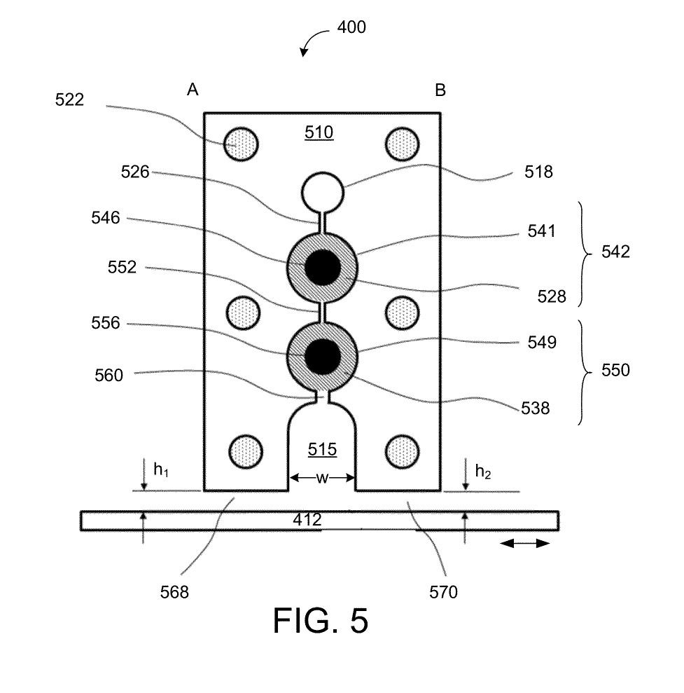

FIG. 5 is a cross sectional view of the plasma reactor 400 taken along line A-B of FIG. 4, according to one embodiment. The plasma reactor 400 is placed above the substrate 412 with gaps 568, 570 of heights h₁, h₂ between the substrate 412 and the plasma reactor 400. Heights h₁ and h₂ may be the same or be different.

A body 510 of the plasma reactor 400 is made of a conductive material such as aluminum, stainless steel or nickel. Materials such as aluminum, stainless steel and nickel are stable and tend to have negligible reaction of radicals or reactive species generated in the plasma reactor. The body 510 is formed with a gas channel 518, cooling medium channels 522, gas holes 526, a first plasma chamber 528, a second plasma chamber 583 and an exposure chamber 515.

The reactivity of radicals or reactive species may drop if their temperature is excessively high. Therefore, the cooling medium channels 522 are provided to circulate cooling water or other cooling medium through the body 510 to cool the body 510, if needed.

Gas is injected into the first plasma chamber 528 of a first sub-plasma reactor 542 via gas holes 526. The first plasma chamber 528 is defined by an inner electrode 546 extending across the plasma reactor 400 and an outer electrode 541 surrounding the inner electrode 546. The outer electrode 541 may be part of the body 510. In one embodiment, the body 510 (and hence, the first electrode) is connected to ground whereas the electrode 546 is connected to a voltage source. As voltage pulse is applied across the electrode 546 and the body 510, plasma of the injected gas is generated in the plasma chamber 528. A first excited gas including radicals or reactive species is generated in the plasma chamber 528 as a result.

The first excited gas from the plasma chamber 528 travels to a second plasma chamber 538 of the second sub-plasma reactor 550 via radical exit 552. The second plasma chamber 538 is defined by an inner electrode 556 extending across the plasma reactor 400 and an outer electrode 549 surrounding the inner electrode 556. The outer electrode 549 may be part of the body 510. As voltage pulses are applied across the inner electrode 556 and the outer electrode 549, plasma is generated in the second plasma chamber 538. As a result, a second excited gas is generated in the second plasma chamber 538. The second excited gas has increased reactivity compared to the first excited gas by having more radicals or reactive species.

To induce the flow of the first excited gas from the first plasma chamber 528 to the second plasma chamber 538, the pressure in the first plasma chamber 528 is higher than the pressure in the second plasma chamber 538.

The second excited gas generated in the second plasma chamber 538 are injected via radical exit 560 into the exposure chamber 515 where the second excited gas travels to substrate 412 for reaction with the substrate 412. The radicals, reactive species in the second excited gas or gas remaining after the second excited gas comes into contact with the substrate 412 travel across gaps 568, 570 for discharge. It is advantageous to set the width w of the exposure chamber 515 to be larger than heights h₁, h₂ of gaps 568, 570 to enable sufficient exposure of the substrate 412 to the second excited gas before the second excited gas is discharged via the gaps 568, 570. In one embodiment, the height of gaps 568, 570 between the body 510 and the substrate 412 is 10 mm to 80 mm. To discharge the second excited gas remaining after injection onto the substrate 412 from the exposure chamber 515 to one side or both sides of the body 510 via one of the gaps 568, 570, the pressure in the exposure chamber 515 is maintained at a higher level than in the gaps 568, 570.

The substrate 412 moves below the body 510 to expose different parts of the substrate 412 to the second excited gas. Due to the increased reactivity of the second excited gas, the exposure of the substrate 412 for a short amount of time is sufficient to process the substrate 412. Hence, the substrate 412 can move across the reaction chamber 515 at a higher speed compared to using a plasma reactor with a single plasma chamber. The plasma reactor 400 advantageously produces the second excited gas with increased reactivity while occupying the same horizontal area as other plasma reactor with a single plasma chamber, and therefore, the plasma reactor 400 enables more efficient use of space in facilities where the plasma reactor 400 is installed.

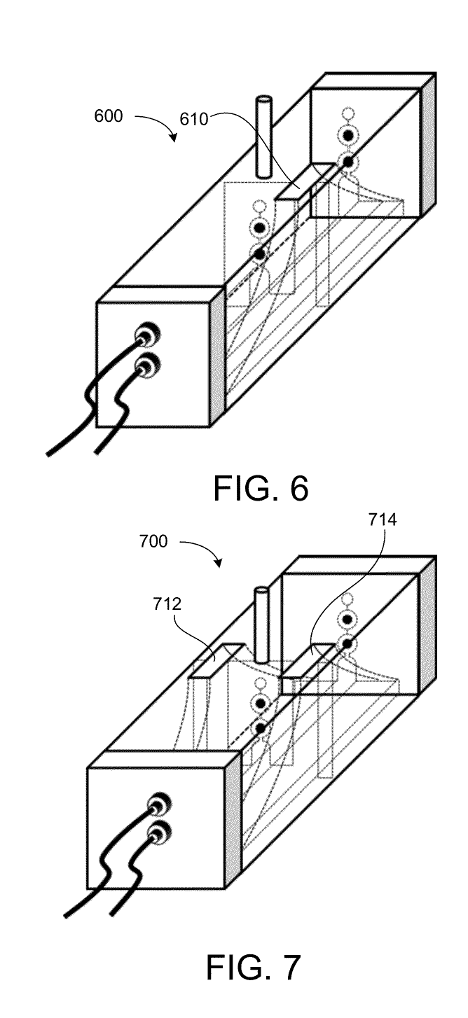

FIG. 6 is a perspective view of a plasma reactor 600 with an exhaust outlet 610, according to one embodiment. The plasma reactor 600 of FIG. 6 is substantially the same as the plasma reactor 400 of FIG. 4 except that the exhaust outlet 610 is formed to discharge the radicals, reactive species of the second excited gas, and gas remaining after coming into contact with the substrate 412. The body of the plasma reactor 600 is formed with the exhaust outlet 610 that extends across the length of the plasma reactor 600.

FIG. 7 is a perspective view of a plasma reactor 700 with a pair of exhaust outlets 712, 714, according to one embodiment. The exhaust outlets 712, 714 are formed on both sides of the plasma reactor 700 to discharge the radicals, reactive species, and gas remaining after coming into contact with the substrate 412. The radicals, reactive species and remaining gas may be discharged at both outlets 712, 714 at the same rate or a different rate.

The plasma reactors 600, 700 of FIGS. 6 and 7 enable efficient discharging of radicals, reactive species or remaining gas without installing exhaust mechanisms separate from the plasma reactors 600, 700.

Plasma Reactors with CCP Sub-Plasma Reactors

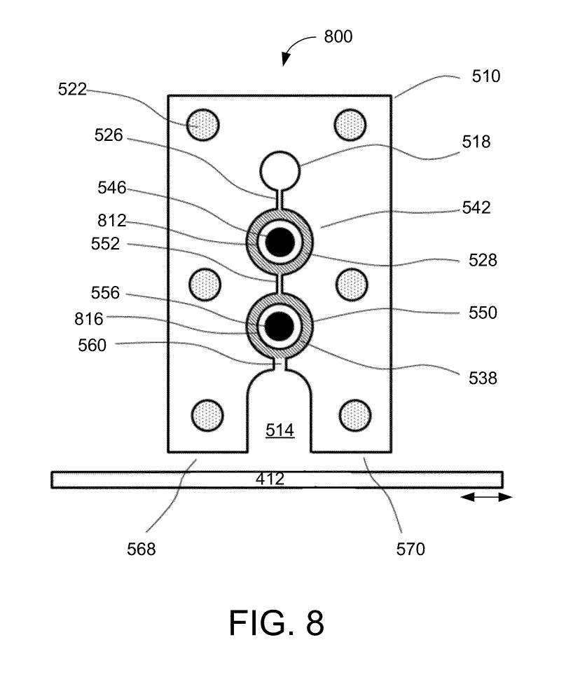

FIG. 8 is a sectional view of a plasma reactor 800 with two capacitively coupled plasma (CCP) type sub-plasma reactors, according to one embodiment. The plasma reactor of FIG. 8 is substantially the same as the plasma reactor of FIG. 5 except that dielectric tubes 812, 816 are placed in the plasma chambers 528, 538 to form CCP type sub-plasma reactors. Instead of using dielectric tubes 812, 816, dielectric material may be coated on the electrodes 546, 556.

By including the dielectric tubes 812, 816 or coating the electrodes 546, 556 with the dielectric material, more stable plasma can be generated. The dielectric material for coating or forming the dielectric tubes 812, 816 may include, among others, ceramic material such as alumina, Mg-doped alumina, magnesia, zirconia or yttria, monocrystalline sapphire without grain boundary or amorphous quartz. To prevent arc from forming, the dielectric tubes 812, 816 may be grinded to have a smooth surface.

A first excited gas is generated in the first plasma chamber 528 and then injected into the second plasma chamber 538. A second excited gas is then generated in the second plasma chamber 538 by further applying voltage between the electrode 556 and the body of the plasma reactor 800.

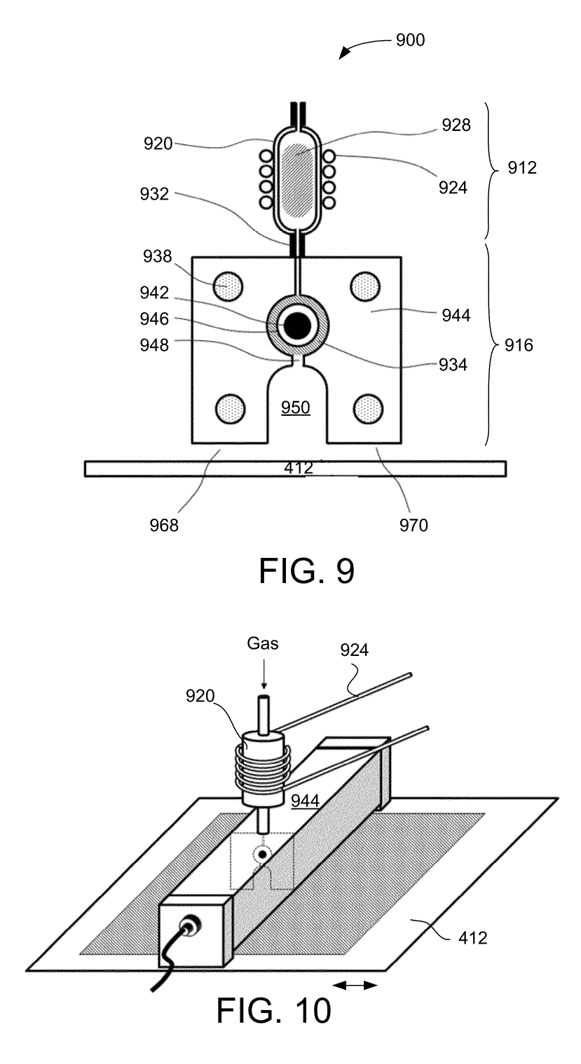

FIG. 9 is a sectional view of a plasma reactor 900 with an inductively coupled plasma (ICP) type sub-plasma reactor 912 and a CCP type sub-plasma reactor 916, according to one embodiment. FIG. 10 is a perspective view of the plasma reactor 900 of FIG. 9, according to one embodiment.

The plasma reactor of FIG. 9 includes an ICP type sub-plasma reactor 912. The ICP type sub-plasma reactor 912 includes a container 920 surrounded by a coil 924. The gas is injected into the container 920 and electric current passes the coil 924 to generate plasma 928 within the container 920. As a result, radicals or reactive species are generated in the container 920. The radicals or reactive species generated by the ICP type sub-plasma reactor 912 are injected into the CCP type sub-plasma reactor 916 via radical exit 932.

Plasma is formed in the plasma chamber 934 of the CCP type sub-plasma reactor 916, increasing the reactivity of the injected radicals or reactive species injected via the radical exit 932.

The CCP type sub-plasma reactor 916 is formed with cooling medium channel 938, the plasma chamber 934 and an exposure chamber 950. The reactivity of radicals or reactive species may drop if their temperature is excessively high. Therefore, the cooling medium channels 938 are provided to circulate cooling water or other coolants through the CCP type sub-plasma reactor 916 to cool the CCP type sub-plasma reactor 916.

The plasma chamber 934 is defined by an electrode 942 extending across the plasma reactor 900 and the body 944 (which functions as another electrode). In one embodiment, the body 944 is connected to ground whereas the electrode 942 is connected to a voltage source. Dielectric tube 946 is placed in the plasma chamber 934. Instead of using dielectric tube 946, dielectric material may be coated on the electrode 942. As voltage pulse is applied across the electrode 942 and the body 944, plasma of the injected gas is generated in the plasma chamber 934. As a result, radicals or reactive species are generated in the plasma chamber 934.

The radicals and reactive species generated in the plasma chamber 934 are injected via radical exit 948 into the exposure chamber 950 where the radicals and the reactive species travel to substrate 412 for reaction with the substrate 412. The radicals, reactive species or gas remaining after the contact with the substrate 412 travel across gaps 968, 970 for discharge. In one embodiment, the height of gaps 968, 970 between the body 944 and the substrate 412 is configured in the same manner as gaps 568, 570 described in detail above with reference to FIG. 5.

In the embodiment of FIG. 9, a CCP type plasma source is used, but different types of plasma sources may be used in place of the CCP type plasma source. For example, electron cyclotron resonance (ECR) plasma may be used as a wave-heated plasma source or ultraviolet (UV) beam may be used as an electrodeless plasma excitation source.

In one embodiment, cooling medium may be provided via the coil 924. The coil 924 may be formed with a passage for the cooling medium to pass through. The cooling medium may cool the ICP type sub-plasma reactor 912. The coil 924 may be made of copper tubing, for example.

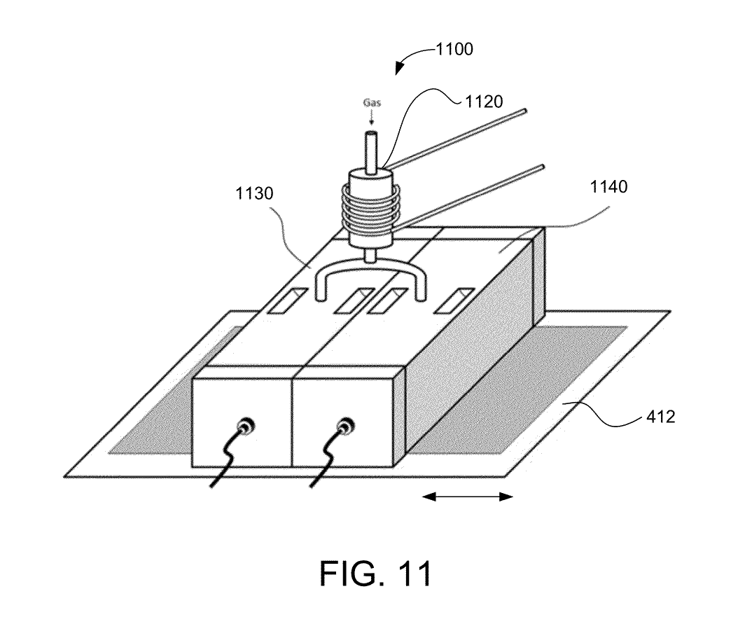

FIG. 11 is a perspective view of a plasma reactor 1100 including an ICP type sub-plasma reactor 1120 and two CCP type sub-plasma reactors 1130, 1140, according to one embodiment. The ICP type sub-plasma reactor 1120 generally generates a higher flow rate of radicals than a CCP type sub-plasma reactor. A first excited gas generated in the ICP type sub-plasma reactor 1120 is sent to the CCP-type sub-plasma reactors 1130, 1140 to generate a second excited gas and a third excited gas that has increased reactivity compared to the first excited gas. The second and third excited gases are then injected onto the substrate 412.

In one embodiment, paths between the ICP type sub-plasma reactor 1120 and the CCP-type sub-plasma reactors 1130, 1140 are cooled down to extend the time that the radicals or reactive species remain active.

Although only two CCP-type sub-plasma reactors 1130, 1140 are described in FIG. 11, a plasma reactor may include more than two CCP-type sub-plasma reactors paired with a single ICP type sub-plasma reactor. Further, the plasma reactor 1100 may include throttle valves to adjust the rate at which the radicals, reactive species or gas are discharged from the plasma reactor.

The sub-plasma reactors of the cascaded plasma reactor generate plasma at lower power than a single large plasma with capacity for generating the same or similar amounts of radicals. Hence, the electrodes of the cascaded plasma reactor will suffer less abrasion and/or resputtering compared to electrodes in a single large plasma reactor. Also, when the cascade plasma reactor is injected with oxygen, the cascade plasma reactor generates more O* radicals than a single large plasma reactor because the first sub-plasma reactor generate O₃ and second sub-plasma reactor amplify or multiply the number of O* radicals by the contributions of ozone molecules.

To perform depositing of Al₂O₃ film by using radical assisted atomic layer deposition (ALD) and the cascaded plasma reactor, trimethylaluminium (TMA) may be used as a source precursor and O₂ gas may be used as a reactant precursor. By moving the substrate 412, TMA molecule layer chemisorbed on substrate 412 reacts with the O* radicals and forms ALD Al₂O₃ film. According to an experiment, Al₂O₃ film deposited using the cascaded plasma reactor exhibited increased breakdown voltage and reduced leakage current compared to Al₂O₃ film deposited using a single large plasma reactor.

Although embodiments are described above with reference to linear or rotational deposition apparatus, the plasma reactors may be used in other devices for performing various operations.

1. A remote plasma reactor comprising:
a first sub-plasma reactor formed with a first chamber configured to generate a first excited gas comprising radicals or reactive species by exciting a gas injected into the first chamber; and
a second sub-plasma reactor communicating with the first sub-plasma reactor to receive the first excited gas, the second sub-plasma reactor formed with a second chamber and configured to generate a second excited gas that is more reactive or more excited than the first excited gas, the second sub-plasma reactor configured to inject the second excited gas onto a substrate.

2. The plasma reactor of claim 1, wherein the first sub-plasma reactor comprises a first inner electrode and a first outer electrode defining the first chamber, voltage difference applied between the first inner electrode and the first outer electrode, and the second sub-plasma reactor comprises a second inner electrode and a second outer electrode defining the second chamber, voltage difference applied between the second inner electrode and the second outer electrode.

3. The plasma reactor of claim 1, wherein the second sub-plasma reactor is formed with an exposure chamber open towards the substrate and having a width larger than a gap between the second sub-plasma reactor and the substrate.

4. The plasma reactor of claim 1, wherein the first sub-plasma reactor and the second sub-plasma reactor comprise a body formed with at least one channel for circulating cooling medium to cool the plasma reactor.

5. The plasma reactor of claim 1, wherein the first and second sub-plasma reactors are capacitively coupled plasma (CCP) type sub-plasma reactors.

6. The plasma reactor of claim 1, wherein the first sub-plasma reactor and the second sub-plasma reactor are of different types.

7. The plasma reactor of claim 6, wherein the first sub-plasma reactor is an inductively coupled plasma (ICP) type sub-plasma reactor and the second sub-plasma reactor is a capacitively coupled plasma (CCP) type sub-plasma reactor.

8. The plasma reactor of claim 6, wherein the first sub-plasma reactor comprises a coil surrounding the first chamber and wherein electric current passes the coil to induce plasma within the first chamber.

9. The plasma reactor of claim 8, further comprising a third sub-plasma reactor connected to the first sub-plasma reactor to receive the first excited gas, the third sub-plasma reactor formed with a third chamber and configured to generate a third excited gas that is more reactive or excited than the first excited gas, the third sub-plasma reactor configured to inject the third excited gas onto the substrate.

10. The plasma reactor of claim 9, wherein the second sub-plasma reactor and the third sub-plasma reactor are placed in tandem over the substrate.

11. The plasma reactor of claim 1, wherein different portions of the substrate are successively injected with the second excited gas as the substrate passes the second sub-plasma reactor.

12. A method of treating a substrate, comprising:
receiving a gas in a first chamber formed in a first sub-plasma reactor and located away from the substrate;
within the first chamber, generating a first excited gas comprising radicals or reactive species;
receiving the first excited gas in a second chamber formed in a second sub-plasma reactor and located away from the substrate;
within the second sub-plasma chamber, generating a second excited gas comprising radicals or reactive species, the second excited gas more reactive or excited than the first excited gas; and
injecting the second excited gas onto the substrate.

13. The method of claim 12, further comprising:
applying voltage difference between a first inner electrode of the first sub-plasma reactor and a first outer electrode of the first sub-plasma reactor, the first inner electrode and the first outer electrode defining the first chamber; and
applying voltage difference between a second inner electrode of the second sub-plasma reactor and a second outer electrode of the first sub-plasma reactor, the second inner electrode and the second outer electrode defining the second chamber.

14. The method of claim 12, wherein the first and second sub-plasma reactors are capacitively coupled plasma (CCP) type sub-plasma reactors.

15. The method of claim 12, wherein the first sub-plasma reactor and the second sub-plasma reactor are of different types.

16. The method of claim 15, wherein the first sub-plasma reactor is an inductively coupled plasma (ICP) type sub-plasma reactor and the second sub-plasma reactor is a capacitively coupled plasma (CCP) type sub-plasma reactor.

17. The method of claim 15, further comprising passing electric current through a coil surrounding the first chamber to induce plasma within the first chamber.

18. The method of claim 17, further comprising:
receiving the first excited gas in a third chamber of a third sub-plasma reactor connected to the first sub-plasma reactor;
generating a third excited gas in the third chamber, the third excited gas more reactive or more excited than the first excited gas; and
injecting the third excited gas onto the substrate.

19. The method of claim 18, wherein the second sub-plasma reactor and the third sub-plasma reactor are placed in tandem over the substrate.

20. The method of claim 12, further comprising passing the substrate under the second sub-plasma reactor to sequentially treat different portions of the substrate by injecting the different portions of the substrate with the second excited gas.
